(19) United States
(12) Patent Application Publication
(10) Pub. No.: US 2014/0104798 A1
(43) Pub. Date: Apr. 17, 2014

(54) HYBRID LAMINATION SUBSTRATE, MANUFACTURING METHOD THEREOF AND PACKAGE SUBSTRATE

(71) Applicant: Samsung Electro-Mechanics Co., Ltd., Suwon (KR)

(72) Inventors: Seung Wook Park, Seoul (KR); Dong Hwan LEE, Suwon (KR); Romero CHRISTIAN, Suwon (KR); Young Do KWEON, Suwon (KR); Jin Gu KIM, Suwon (KR)

(73) Assignee: Samsung Electro-Mechanics Co., Ltd., Suwon (KR)

(21) Appl. No.: 14/055,335

(22) Filed: Oct. 16, 2013

(30) Foreign Application Priority Data
Oct. 16, 2012 (KR) 10-2012-0114668

(51) Int. Cl. H05K 1/11

(52) U.S. Cl. CPC H05K 1/11
USPC 361/764; 430/315; 361/761; 174/255; 428/195.1

(57) ABSTRACT

Disclosed herein are a hybrid lamination substrate and a manufacturing method thereof. The hybrid lamination substrate includes: a core layer; at least one first insulating layer that is made of a photosensitive resin material and is formed on an upper portion, a lower portion, or upper and lower portions of the core layer; and at least one second insulating layer that is made of a non-photosensitive resin material and is formed on the upper portion, the lower portion, or the upper and lower portions of the core layer. Further, a package substrate including the same and a manufacturing method of a hybrid lamination substrate are proposed.

### CROSS REFERENCE(S) TO RELATED APPLICATIONS

This application claims the benefit under 35 U.S.C. Section 119 of Korean Patent Application Serial No. 10-2012-0114668 entitled “Hybrid Lamination Substrate, Manufacturing Method Thereof, And Package” filed on Oct. 16, 2012, which is hereby incorporated by reference in its entirety into this application.

### BACKGROUND OF THE INVENTION

1. Technical Field

The present invention relates to a hybrid lamination substrate, a manufacturing method thereof, and a package substrate, and more particularly, to a hybrid lamination substrate in which an insulating layer of a photosensitive material and an insulating layer of a non-photosensitive material are laminated in a hybrid type, a manufacturing method thereof, and a package substrate.

2. Description of the Related Art

In case of a PCB according to the related art, a lamination substrate is manufactured by using only one of a photo via method or a laser via method. In this case, there are advantages in that the lamination can be easily made and equipments, and the like, can be used consistently. However, the photosensitive material is expensive, but can be formed at a high density using a photo via and may have the reduced burden of costs depending on the number of vias. In the case of prepreg (PPG) lamination using the laser via, the burden of costs is reduced but the laminated number may be increased due to the limitation of the fine patterning and via machining cost may be increased as the number of vias is increased with the development of devices.

Generally, for example, in the case of a mobile terminal, one layer and a bottom are applied with a shield and a pattern for SMT, such that it is difficult to perform routing and an inner layer has functions of each layer such as a signal transmission line, a ground (GND), a power distribution network (PDN), and the like, for each layer. In this case, as in the related art, when only the photo via layer is applied, the via size may be reduced and thus, the layer may be reduced due to the use of the high density via and in the case of the photo via, the via size may be freely controlled according to a mask pattern size to increase a freedom in design but the burden of costs is increased. Meanwhile, when the laser via layer is applied, the laminated number is increased due to the limitation of the fine patterning, costs may be increased according to the increase in the machined number of laser vias, and the like.

Further, a recent substrate market demands a substrate having a thin type low layer and low warpage characteristics. Further, in order to meet the demands, a technology of implementing a high-density substrate is required. However, in order to meet high density, the number of layers needs to be increased, such that the thickness of the substrate is increased. In order to meet all the demands, the via size of the substrate needs to be reduced and the pattern needs to be fine. In this case, in order to reduce the via size and miniaturize the pattern, requirements of a design for maintaining the laminated number may be increased and costs for performing the process may be increased.

### RELATED ART DOCUMENT

### Patent Document

(Patent Document 1) U.S. Pat. No. 6,594,893 (published on Jul. 22, 2003)
(Patent Document 2) U.S. Pat. No. 6,270,607 (published on Aug. 7, 2001)

### SUMMARY OF THE INVENTION

An object of the present invention is to simplify a structure of a substrate and minimize process costs, by appropriately mixing and laminating a photosensitive substrate material and a non-photosensitive substrate material to which the fine via machining can be subjected at the time of manufacturing a lamination substrate.

Another object of the present invention is to implement optimal substrate structure and process by resolving design and structure problems.

According to a first exemplary embodiment of the present invention, there is provided a hybrid lamination substrate, including: a core layer; at least one first insulating layer that is made of a photosensitive resin material and is formed on an upper portion, a lower portion, or upper and lower portions of the core layer; and at least one second insulating layer that is made of a non-photosensitive resin material and is formed on the upper portion, the lower portion, or the upper and lower portions of the core layer.

A hybrid lamination structure in which the first and second insulating layers are mixed and laminated on the upper portion, the lower portion, or the upper and lower portions of the core layer may be formed.

A through hole may be formed within the hybrid lamination structure so as to interconnect the upper and lower portions of the insulating layer.

The first insulating layer may include at least one fine via having a smaller size that connects patterns formed on the upper and lower portions thereof, and the second insulating layer may include at least one wide via having a larger size that connects patterns formed on the upper and lower portions thereof.

The fine via may be a photo via and a fine pattern layer formed on the upper portion of the first insulating layer and including a signal transmission line may be connected with the photo via, and the wide via may be a laser via and a wide pattern layer formed on the upper portion of the second insulating layer and including at least any one of a ground and a power distribution network (PDN) may be connected with the laser via.

The fine via may be a photo via and the wide via may be a laser via and the plurality of photo vias formed on the first insulating layer may have at least two different sizes.

The photosensitive resin material of the first insulating layer may include at least any one selected from photosensitive polyhydroxystyrene (PHS), photosensitive polybenzoxazole (PBC)), photosensitive polyimide (PI), photosensitive benzocyclobutene (BCB), photosensitive polysiloxane, photosensitive epoxy, and novolac resin.

The second insulating layer may be made of any one of prepreg (PPG), ajinomoto build-up film (ABF), resin coated copper (RCC), liquid crystal polymer (LCP), and teflon.

The hybrid lamination substrate may further include: a solder resist (SR) layer that is formed at an outer layer of the lamination substrate.

The core layer may include a cavity and the cavity may have electronic devices embedded therein and the core layer in which the electronic devices are embedded may be laminated with the first and second insulating layers.

The hybrid lamination structure in which the first and second insulating layers are mixed and laminated may be provided with the cavity and the cavity may have electronic devices embedded therein.

According to a second exemplary embodiment of the present invention, there is provided a package substrate including an IC, including: the hybrid lamination substrate as described above; and an IC chip mounted on the hybrid lamination substrate or mounted therein.

The IC chip may be mounted at an outside of the hybrid lamination structure in which first and second insulating layers are mixed and laminated on an upper portion, a lower portion, or upper and lower portions of the core layer, and an insulating layer close to the IC chip may be the first insulating layer and an inside of the insulating layer far away from the IC chip may be provided with the second insulating layer.

The IC chip may be embedded in a cavity formed at an inside of the hybrid lamination structure in which first and second insulating layers are mixed and laminated on an upper portion, a lower portion, or upper and lower portions of the core layer.

According to a third exemplary embodiment of the present invention, there is provided a manufacturing method of a hybrid lamination substrate, including: preparing a core layer and forming a circuit pattern on the core layer; and laminating at least one first insulating layer made of a photosensitive material and at least one second insulating layer made of a non-photosensitive material on an upper portion, a lower portion, or upper and lower portions of the core layer and forming a pattern.

In the laminating of the first and second insulating layers, a hybrid lamination structure in which the first and second insulating layers are mixed and laminated on the upper portion, the lower portion, or the upper and lower portions of the core layer may be formed.

In the laminating of the first and second insulating layers and the forming of the pattern, at least one fine photo via having a smaller size that connects upper and lower patterns of the first insulating layer may be formed by performing exposure, development, and plating on the laminated first insulating layer and at least one wide laser via having a larger size that connects patterns formed on upper and lower portions of the second insulating layer may be formed by performing laser drilling on the laminated second insulating layer.

In the laminating of the first and second insulating layers and the forming of the pattern, a fine pattern layer including a signal transmission line may be formed on the upper portion of the first insulating layer so as to be connected with the fine photo via, and a wide pattern layer including any one of a ground and a power distribution network (PDN) may be formed on the upper portion of the second insulating layer so as to be connected with the wide laser via.

The manufacturing method of a hybrid lamination substrate may further include: after the laminating of the first and second insulating layers and the forming of the pattern, forming a solder resist (SR) layer at an outside of the hybrid lamination substrate.

### BRIEF DESCRIPTION OF THE DRAWINGS

FIG. 1A is a cross-sectional view schematically illustrating a hybrid lamination substrate according to one embodiment of the present invention.

FIG. 1B is a cross-sectional view schematically illustrating a hybrid lamination substrate according to another embodiment of the present invention.

FIGS. 2A to 2F are a diagram schematically illustrating a manufacturing method of the hybrid lamination substrate according to FIG. 1.

FIG. 3 is a cross-sectional view schematically illustrating a hybrid lamination substrate according to another embodiment of the present invention.

FIGS. 4A to 4F are a diagram schematically illustrating a manufacturing method of a hybrid lamination substrate according to FIG. 3.

FIG. 5 is a diagram schematically illustrating a hybrid lamination structure of a hybrid lamination substrate according to another exemplary embodiment of the present invention.

### DESCRIPTION OF THE PREFERRED EMBODIMENTS

Exemplary embodiments of the present invention for accomplishing the above-mentioned objects will be described with reference to the accompanying drawings. In the present specification, the same reference numerals will be used to describe the same components, and a detailed description thereof will be omitted in order to allow those skilled in the art to easily understand the present invention.

In the specification, it will be understood that unless a term such as ‘directly’ is not used in a connection, coupling, or disposition relationship between one component and another component, one component may be ‘directly connected to’, ‘directly coupled to’ or ‘directly disposed to’ another element or be connected to, coupled to, or disposed to another element, having the other element intervening therebetween.

Although a singular form is used in the present description, it may include a plural form as long as it is opposite to the concept of the present invention and is not contradictory in view of interpretation or is used as a clearly different meaning. It should be understood that “include”, “have”, “comprise”, “be configured to include”, and the like, used in the present description do not exclude presence or addition of one or more other characteristic, component, or a combination thereof.

The accompanying drawings referred in the present description may be ideal or abstract examples for describing exemplary embodiments of the present invention. In the accompanying drawings, a shape, a size, a thickness, and the like, may be exaggerated in order to effectively describe technical characteristics.

Further, in the present specification, “first” and “second” is an expression to differentiate one component from other components rather than representing number or order.

First, a hybrid lamination substrate according to one exemplary embodiment of the present invention will be described with reference to the accompanying drawings. In this case, reference numerals that are not shown in the accompanying drawings may be reference numerals in other drawings showing the same configuration.

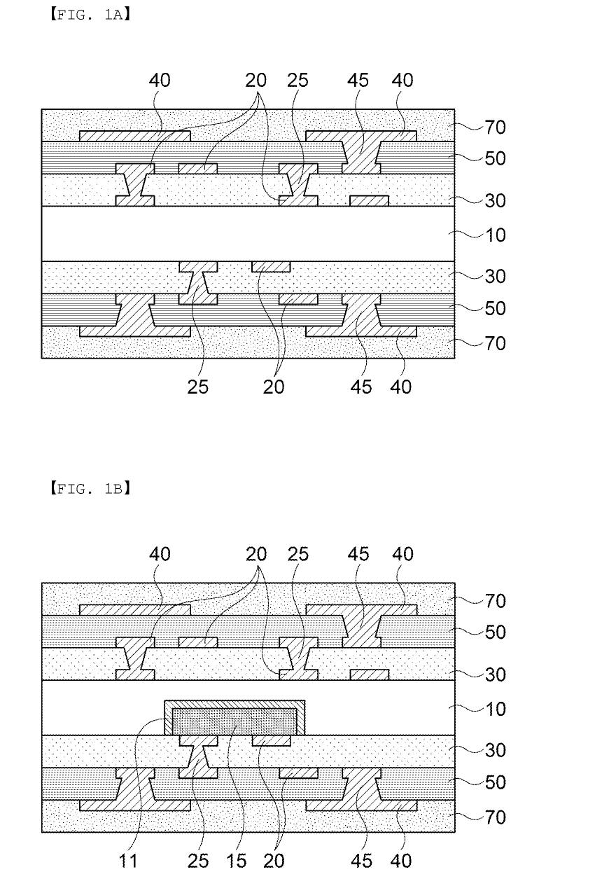

FIG. 1A is a cross-sectional view schematically illustrating a hybrid lamination substrate according to one embodiment of the present invention, FIG. 1B is a cross-sectional view schematically illustrating a hybrid lamination substrate according to another of the present invention, FIG. 3 is a cross-sectional view schematically illustrating a hybrid lamination substrate according to another embodiment of the present invention, FIG. 5 is a diagram schematically illustrating a hybrid lamination structure of a hybrid lamination substrate according to another exemplary embodiment of the present invention.

Referring to FIGS. 1A, 1B, 3, and 5, a hybrid lamination substrate according to an exemplary embodiment of the present invention may be configured to include a core layer 10, at least one first insulating layer 30, and at least one second insulating layer 50. Further, in one example, as illustrate in FIGS. 1A, 1B, 3, and/or 5, the hybrid lamination substrate may further include a solder resist layer 70. Further, in one example, the hybrid lamination substrate may be a hybrid lamination substrate in which electronic devices 15 are embedded. Exemplary embodiments of the hybrid lamination substrate may be applied to mobile devices but are not limited thereto.

Referring to FIGS. 1A, 1B, 3, and/or 5, for example, the core layer 10 is formed at a center of the lamination substrate and maintains stability against a warpage of the lamination substrate. For example, as illustrated in FIGS. 1A, 1B and 3, circuit patterns may be formed on a core layer 10. In this case, the circuit patterns may be fine patterns 20 such as a signal transmission line, and the like, or/and wide patterns 40 such as a ground, a power distribution network, and the like. Generally, the core layer 10 may be made of CCL using prepreg that is used in a substrate or materials such as silicon, glass, ceramic, and the like, that are used in interposer, and the like, but a material of the core layer 10 is not limited thereto. In addition, referring to FIG. 5, for example, the core layer 10 may be provided with a through hole 66 that interconnects the circuit patterns formed on the upper and lower portions thereof.

Next, a first insulating layer 30 and a second insulating layer 50 will be described with reference to FIGS. 1A, 1B, 3, and/or 5. At least one first insulating layer 30 may be disposed on the upper portion, the lower portion, or the upper and lower portions of the core layer 10. FIGS. 1A, 1B and 3 illustrate only the first insulating layers 30 each of which is disposed on the upper and lower portions of the core layer 10 and as illustrated in FIG. 5, a plurality of first insulating layers 30 may be disposed on the upper portion, the lower portion, or the upper and lower portions of the core layer 10. Further, at least one second insulating layer 50 may also be disposed on the upper portion, the lower portion, or the upper and lower portions of the core layer 10. In this case, the upper portion, the lower portion, or the upper and lower portions of the core layer 10 may directly contact the core layer 10 but may contact the core layer 10, having another insulating layer or a plurality of insulating layers therebetween. The upper portion, the lower portion, or the upper and lower portions of the core layer 10 may be provided with at least one first insulating layer 30 and at least one second insulating layer 50, such that the substrate manufacturing costs, the structural stability of the substrate, and the high density demand can be satisfied.

In this case, the first insulating layer 30 may be made of a photosensitive resin material. For example, the first insulating layer 30 may be formed by laminating a photosensitive resin film or applying a photosensitive resin paste or a liquid phase. In this case, in one example, the photosensitive resin material may include at least any one selected from photosensitive polyhydroxystyrene (PHS), photosensitive polybenzoxazole (PBO), photosensitive polyimide (PI), photosensitive benzocyclobutene (BCB), photosensitive polysiloxane, photosensitive epoxy, and novolac resin. The first insulating layer 30 is made of the photosensitive resin material, such that the fine photo via having a small size may be formed on the first insulating layer 30 by, for example, exposure and development.

Meanwhile, the second insulating layer 50 may be made of a non-photosensitive resin material. The second insulating layer 50 may be made of, for example, materials such as liquid crystal polymer (LCP), PPG (FR 1, 2, 3, 4), teflon, ajinomoto build up film (ABF), resin coated copper (RCC), and the like, but the exemplary embodiment of the present invention are not limited thereto. In one example, the second insulating layer 50 may be made of any one of prepreg (PPG), ajinomoto build-up film (ABF), resin coated copper (RCC), liquid crystal polymer (LCP), Teflon. For example, the second insulating layer 50 may be formed by laminating the build-up film such as prepreg (PPG). The second insulating layer 50 uses the non-photosensitive resin material, such that costs may be more saved than using the photosensitive material and an appropriate via 45 may be formed by using a CNC or a laser. For example, a wide laser via 45 having a large size may be formed on the second insulating layer 50 by laser drilling.

Further, referring to FIGS. 1A, 1B, 3, and/or 5, in one example, the first insulating layer 30 and the second insulating layer 50 form the hybrid lamination structure. The hybrid lamination structure of the first insulating layer 30 and the second insulating layer 50 are formed on the upper portion, the lower portion, or the upper and lower portions of the core layer 10. In this case, the first insulating layer 30 may be alternately laminated with the second insulating layer 50 and although not illustrated, may be laminated in a form in which at least one first insulating layer 30 is inserted into the middle of the plurality of second insulating layers 50. For example, as illustrated in FIG. 1A, the hybrid lamination structure of the first and second insulating layers 30 and 50 may include a hybrid structure in which the second insulating layer 50 is formed on the first insulating layer 30. In this case, as illustrated in FIG. 5, the first insulating layer 30 may be laminated on the hybrid structure in which the second insulating layer 50 is formed on the first insulating layer 30. Alternatively, as illustrated in FIG. 3, the hybrid lamination structure of the first and second insulating layers 30 and 50 may include the hybrid structure in which the first insulating layer 30 is formed on the second insulating layer 50 and as illustrated in FIG. 5, the hybrid structure in which the second insulating layer 50 is formed on the first insulating layer 30 and the hybrid structure in which the first insulating layer 30 is formed on the second insulating layer 50 may also be mixed. According to the hybrid lamination structure of the first insulating layer 30 and the second insulating layer 50, the high density can be implemented and the structural stability against the warpage of the lamination substrate, and the like, can be obtained. Further, since the lamination structure is changed if necessary, the material may be laminated asymmetrically.

In this case, describing one example with reference to FIG. 5, through holes 65, 65′, and 65″ punched by CNC or laser may be formed so that the upper and lower portions of the first and second insulating layers 30 and 50 are interconnected with each other within the hybrid lamination structure. Therefore, the first insulating layer 30 may be further provided with the fine photo via 25 by, for example, exposure and development and the through holes 65, 65′, and 65″ punched by CNC or laser. In FIG. 5, reference numeral 65′ represents the through hole punched by laser, reference numeral 65″ represents the through hole punched by CNC, and the through holes may be fully filled by plating, and the like, and the upper and lower portions of the through holes may be interconnected with each other by a process such as outer wall plating, and the like.

Although not illustrated, according to another example, in the hybrid lamination structure of the first and second insulating layers 30 and 50, an adhesive layer (not illustrated) may be interposed between the first insulating layer 30 and the second insulating layer 50 so as to firm the coupling between heterogeneous insulators.

Further, according to one example, the first insulating layer 30 and the second insulating layer 50 will be described in more detail with reference to FIGS. 1A, 1B, 3, and/or 5.

First, the first insulating layer 30 may be provided with at least one fine via 25 having a small size that interconnects the patterns formed on the upper and lower portions thereof. In the present invention, the fine via 25 means a via with a structure having a smaller diameter than the wide via 45 and may be formed by a photo method using, for example, the exposing/developing processes.

In one example, the fine via 25 formed on the first insulating layer 30 may be the fine photo via 25 that is formed by, for example, the photo method. When the first insulating layer 30 of the photosensitive resin material is provided with the via by the photo method using the exposing/developing processes or is physically machined, the fine via having a smaller size than the via formed by using, for example, CNC or laser punching may be formed. The high density can be implemented by forming the fine photo via 25 on the first insulating layer 30 and therefore, the first insulating layer 30 may be formed in a portion at which the high density is required, in the hybrid lamination structure of the first insulating layer 30 and the second insulating layer 50. In this case, the via having a larger size may be freely formed on the first insulating layer 30 and if necessary, the wide via by, for example, the laser machining in addition to the fine via 25 or the through holes 65, 65′ and 65″ by the CNC or laser machining illustrated in FIG. 5 may also be formed on the first insulating layer 30. In another example, the plurality of photo vias 25 having at least two different sizes and formed on the first insulating layer 30 may be applied. The size of the photo via 25 may be controlled according to the mask pattern size.

Further, in one example, the fine pattern layer 20 may be formed on the upper portion of the first insulating layer 30. The fine pattern layer 20 formed on the upper portion of the first insulating layer 30 may include the signal transmission line and may be connected with the photo via 25. That is, the pattern formed on the upper portion of the first insulating layer 30 may be the fine pattern layer 20 such as the signal transmission line and the fine via 25 formed on the first insulating layer 30 connected with the fine pattern layer 20 such as the signal transmission line formed on the upper portion of the first insulating layer 30 may be a part of the fine pattern 20, together with the fine pattern layer 20 formed on the upper portion of the first insulating layer 30. Meanwhile, the pattern formed on the lower portion of the first insulating layer 30 connected with the fine via 25 of the first insulating layer 30 may be a pattern that is formed on the upper portion of the core layer 10 forming the lower layer of the first insulating layer 30 illustrated in FIG. 1, the second insulating layer 50 illustrated in FIG. 3, or another first insulating layer 30 (not illustrated). For example, FIG. 1A illustrates that the fine pattern 20 such as the signal transmission line is formed on the upper portion of the core layer 10 forming the lower layer of the first insulating layer 30, but as illustrated in FIG. 3, the wide pattern 40 such as the ground, the power distribution network, and the like, may also be formed on the core layer 10 that is on the lower portion of the first insulating layer 30.

For example, the fine pattern layer 20 such as the signal transmission line that is formed on the upper portion of the first insulating layer 30 may be formed using, for example, a copper clad layer (CCL) and may be formed by, for example, MSAP or AMSAP process. In this case, the fine pattern layer 20 is formed on the upper portion of the first insulating layer 30 using the photo method, together with the photo via 25 penetrating through the inside of the first insulating layer 30, such that the high-density pattern layer may be formed. Meanwhile, even when the fine pattern layer 20 and if necessary, the low-density pattern need to be formed on the upper portion of the first insulating layer 30, the wide pattern layer 40 may be freely formed.

To be continue, referring to FIGS. 1A, 1B, 3, and/or 5, the second insulating layer 50 may include at least one wide via 45 having a larger size that interconnects the patterns formed on the upper and lower portions thereof. In this case, since the second insulating layer 50 is made of the non-photosensitive resin material, it is difficult to form the wide via 45 formed on the second insulating layer 50 by the photo method using the exposing/developing processes, such that the wide via 45 may be a wide laser via 45 formed by using, for example, laser drilling. The wide laser via 45 using the laser drilling has a larger diameter than that of the fine photo via 25 that is generally made of the photosensitive resin material and formed by the photo method.

Further, in another example, the wide pattern layer 40 may be formed on the upper portion of the second insulating layer 50. The wide pattern layer 40 formed on the upper portion of the second insulating layer 50 may include at least any one of the ground and the power distribution network (PDN). In this case, the wide pattern layer 40 may be connected with the wide via 45 (for example, the laser via 45) having a larger size that is formed on the second insulating layer 50. For example, the laser via 45 by the laser machining penetrates through the inside of the second insulating layer 50 to connect the wide pattern layer 40 formed on the upper portion thereof with the pattern formed on the lower portion thereof. The ground, the power distribution network (PDN) line, and the like, do not need to be high density, such that the laser via 45 and the wide pattern layer 40 may be formed on the second insulating layer 50 formed in the build-up film of the non-photosensitive material such as, for example, prepreg. That is, the laser via 45 formed on the second insulating layer 50 and the wide pattern layer 40 such as, for example, the ground, the power distribution network (PDN) pattern, and the like, that is formed on the upper portion of the second insulating layer 50 may be a part of the wide pattern 40. Further, the pattern formed on the lower portion of the second insulating layer 50 may be a pattern that is formed on the upper portion of the core layer 10 forming the lower layer of the second insulating layer 50 illustrated in FIG. 3, the first insulating layer 30 illustrated in FIG. 1A, or another second insulating layer (not illustrated).

Further, the wide pattern layer 40 such as the ground or the power distribution network (PDN) may be formed on the upper portion of the second insulating layer 50 or the copper clad layer (CCL) is machined and thus, the fine pattern such as the signal line may be freely formed by, for example, the MSAP or AMSAP process. For example, the wide pattern layer 40 and the fine pattern 20 may be formed on the second insulating layer 50. However, the second insulating layer 50 may be made of the non-photosensitive material and therefore, it is difficult to form the via penetrating through the second insulating layer 50 as the photo via by the photo method, such that the wide via 45 may be formed by, for example, the laser punching.

As described above, according to the hybrid lamination structure of the first insulating layer 30 and the second insulating layer 50, only the first insulating layer 30 on which the photo via 25 that is the fine via 25 is formed is not laminated on the core layer 10, but the first insulating layer 30 and the second insulating layer 50 on which the laser via 45 that is the wide via 45 is formed are mixed and laminated, such that costs may be saved and the structural stability against the warpage, and the like, of the lamination substrate may be obtained. That is, the portion at which the high density is required uses the first insulating layer 30 on which the fine photo via 25 and the fine pattern layer 20 are formed and the portions that may be formed at the low density, for example, the ground, the power distribution network (PDN) pattern, and the like, use the second insulating layer 50 on which the wide laser via 45 and the wide pattern layer 40 are formed, such that the manufacturing costs, the structural stability of the substrate, and the high density demand man be satisfied.

Next, another example will be described with reference to FIGS. 1A, 1B and 3.

In this case, as illustrated in FIGS. 1A, 1B and 3, a solder resist (SR) layer 70 may further be provided at the outside of the hybrid lamination substrate, for example, the outside of the hybrid lamination structure of the first and second insulating layers 30 and 50. The solder resist layer 70 serves to protect a wiring layer on which the circuit pattern is formed. The solder resist layer 70 may be made of, for example, the photosensitive resin material. Further, although not illustrated, the solder resist layer 70 may also be provided with the via, and the like, so as to be electrically connected with the outside of the lamination substrate.

Next, another example of the hybrid lamination substrate will be described with reference to FIG. 1B.

According to one example, in the hybrid lamination substrate according to the foregoing exemplary embodiments, the core layer 10 includes a cavity 11 and electronic devices 15 may be embedded in the cavity. The embedded electronic devices 15 may be passive devices such as a capacitor, and the like, or active devices. Generally, any electronic device that may be applied to the substrate in which the electronic devices are embedded may be used. Further, the first and second insulating layers 30 and 50 may be laminated on the core layer 10 in which electronic devices 15 are embedded. For example, the hybrid lamination structure in which the first and second insulating layers 30 and 50 are mixed and laminated may be laminated on the upper portion, the lower portion, or the upper and lower portions of the core layer 10 in which electronic devices 15 are embedded.

Alternatively, in another example, although not illustrated, in the hybrid lamination substrate according to the foregoing exemplary embodiments, the cavity (not illustrated) is formed in the hybrid lamination structure in which the first and second insulating layers 30 and 50 are mixed and laminated and electronic devices (not illustrated) may be embedded in the cavity.

Next, a package substrate according to a second exemplary embodiment of the present invention will be described in detail. In this case, the hybrid lamination substrate according to the foregoing exemplary embodiments and FIGS. 1A, 1B, 3, and 5 may be referenced and therefore, the overlapping description thereof will be omitted.

Although not illustrated, the package substrate including IC according to one example includes the hybrid lamination substrate and the IC chip (not illustrate) according to any one of the foregoing first exemplary embodiments. In this case, the IC chip (not illustrated) is embedded on or in the hybrid lamination substrate according to the foregoing first exemplary embodiment.

For example, although not illustrated, in one example, the IC chip (not illustrated) may be mounted at the outside of the hybrid lamination structure in which the first and second insulating layers 30 and 50 are mixed and laminated on the upper portion, the lower portion, or the upper and lower portions of the core layer 10. In this case, the insulating layer close to the IC chip (not illustrated) may be the first insulating layer 30 and the inside of the insulating layer far away from the IC chip (not illustrate) may be provided with the second insulating layer 50. That is, the IC chip (not illustrated) is formed at the high density and therefore, the first insulating layer 30 is disposed at a position close to the IC chip (not illustrated) on which the high-density pattern may be formed and the portions that may be formed at a low-density pattern, that is, the second insulating layer 50 is formed with the pattern, such that the manufacturing costs, the structural stability, and the high density of the package substrate may be satisfied.

Further, although not illustrated, in one example, the IC chip (not illustrated) may be embedded in the cavity (not illustrated) that is formed at the inside of the hybrid lamination structure in which the first and second insulating layers 30 and 50 are mixed and laminated on the upper portion, the lower portion, or the upper and lower portions of the core layer 10. In this case, the portion electrically connected with the IC chip (not illustrated) may be, for example, the first insulating layer 30 on which the fine pattern 20 is formed.

Next, a manufacturing method of the hybrid lamination substrate according to a third exemplary embodiment of the present invention will be described in detail with reference to the accompanying drawings. In this case, the hybrid lamination substrate according to the foregoing exemplary embodiments and FIGS. 1A, 1B, 3, and 5 may be referenced and therefore, the overlapping description thereof will be omitted.

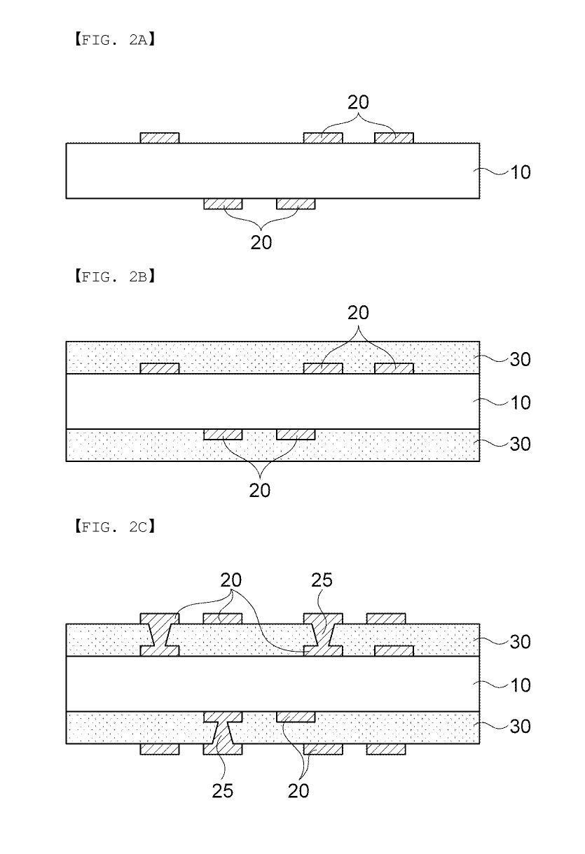

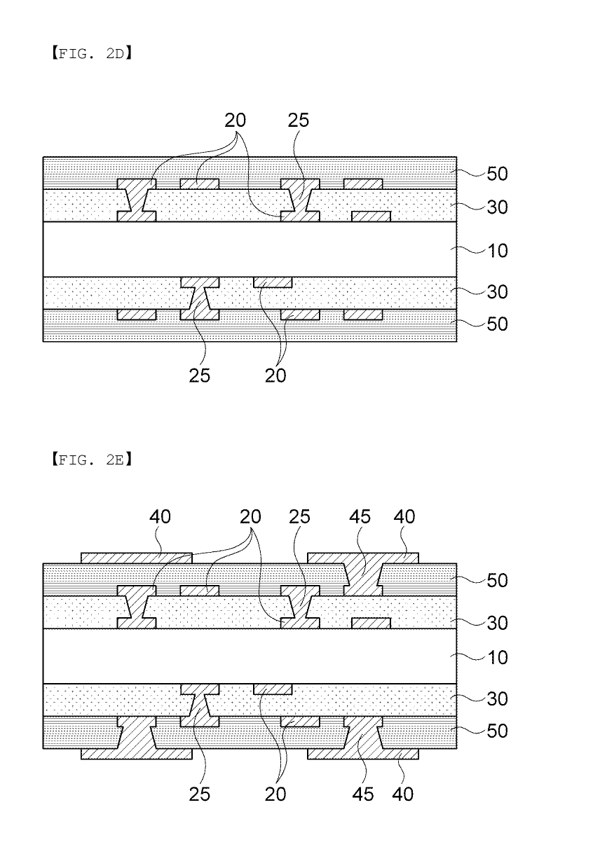

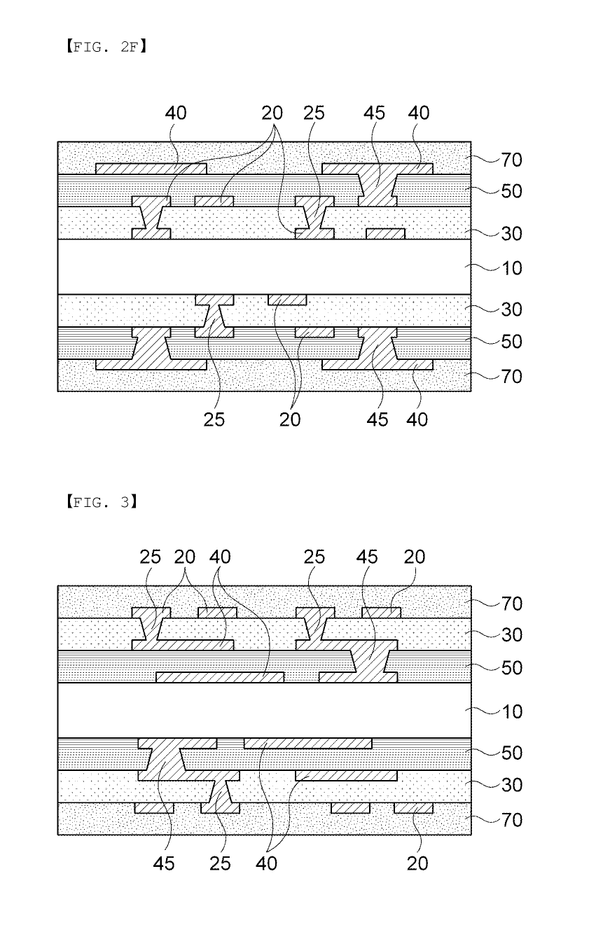

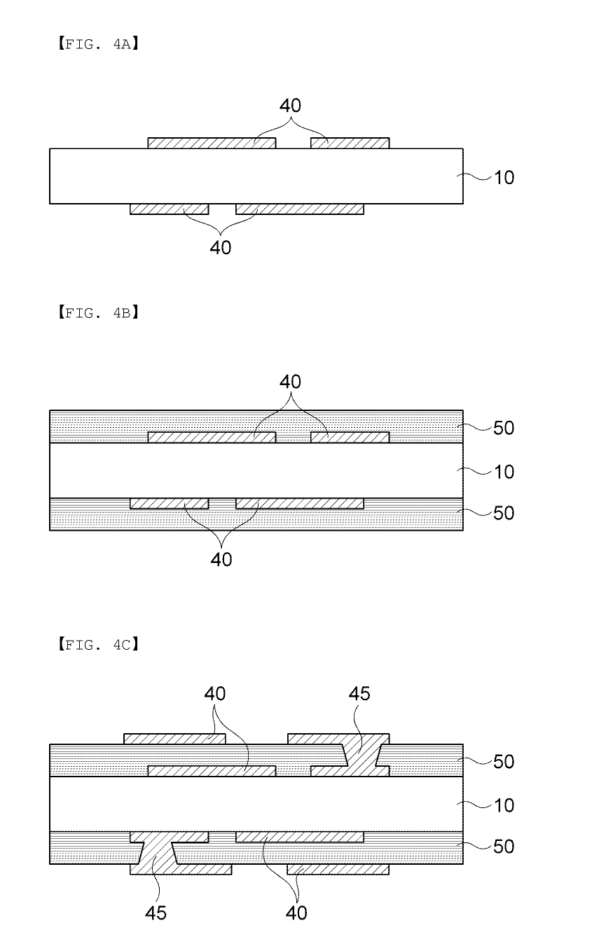

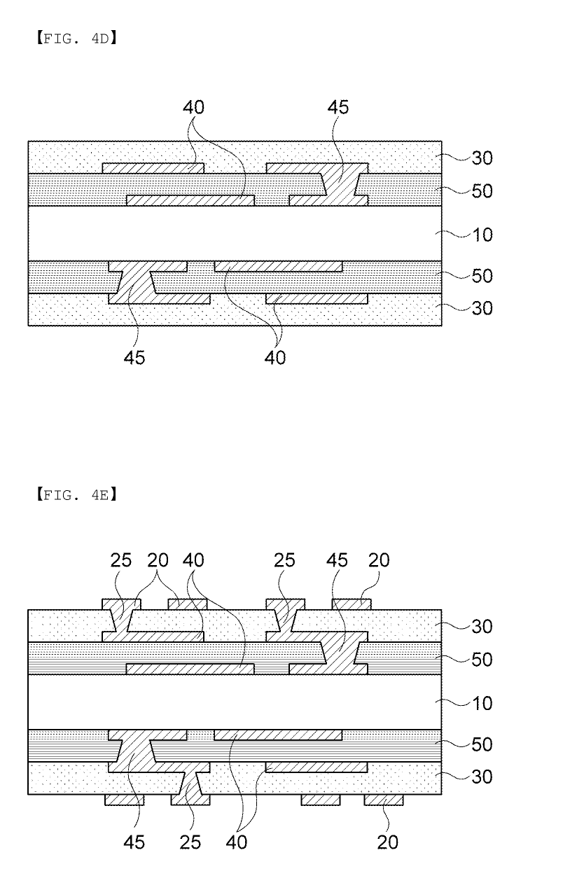

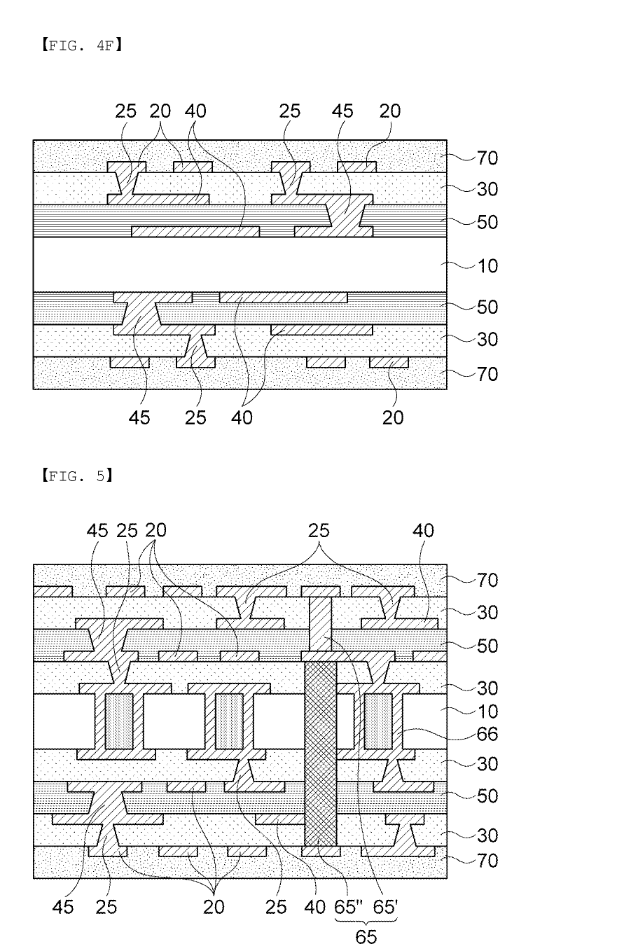

FIGS. 2A to 2F are a diagram schematically illustrating a manufacturing method of the hybrid lamination substrate according to FIG. 1A and FIGS. 4A to 4F are a diagram schematically illustrating a manufacturing method of a hybrid lamination substrate according to FIG. 3.

In detail, FIGS. 2A and 4A illustrate the core layer 10 on which the circuit pattern is formed, FIG. 2B illustrates the first insulating layer 30 that is laminated on the core layer 10, and FIG. 4B illustrates the second insulating layer 50 that is laminated on the core layer 10. FIGS. 2C and 4C each illustrate an appearance in which the circuit patterns are formed on the first insulating layer 30 and the second insulating layer 50 and a via is formed in the inside thereof and FIGS. 2D and 4D each illustrate an appearance in which the second insulating layer 50 and the first insulating layer 30 are each illustrated on the lower layer on which the circuit pattern is formed. FIGS. 2E and 4E each illustrate an appearance in which the circuit patterns are formed on the second insulating layer 50 and the first insulating layer 30 and the via is formed in the inside thereof and FIGS. 2F and 4F illustrate a structure in which the solder resist layer 70 is added.

Referring to FIGS. 2A to 2E or/and FIGS. 4A to 4E, the manufacturing method of the hybrid lamination substrate according to one example may include forming the circuit pattern on the core layer (see FIG. 2A or/and FIG. 4A) and forming the hybrid lamination structure (see FIGS. 2B to 2E or/and FIGS. 4B to 4E). Further, referring to FIG. 2F or/and 4F, in another exemplary embodiment, the manufacturing method of the hybrid lamination substrate may further include forming the solder resist layer 70.

Referring to FIG. 2A or/and FIG. 4A, the core layer 10 is first prepared and the circuit pattern is formed on the core layer 20. In this case, the circuit patterns formed on the core layer 10 may be the fine pattern 20 (see FIG. 4A) such as the signal transmission line, and the like or/and the wide pattern 40 (see FIG. 2A) such as the ground, the power distribution network, and the like. The circuit pattern of the core layer 10 may be implemented by forming, for example, the copper clad layer (CCL) on the core layer 10 and then, the etched or patterned copper clad layer (CCL) on the core layer 10. The circuit pattern on the core layer 10 having the copper clad layer (CCL) may be generally formed by a tenting process based on CCL etching and the modified semi-additive process (MSAP), the advanced modified semi-additive process (AMSAP), and the like, that forms the pattern by the plating using the CCL as the seed layer. In this case, the circuit pattern formed by the MSAP or the AMSAP may be formed to be finer than the tenting process. The circuit patterning process of the surface of the core layer 10 may be selectively applied according to the design capability that is required in the layer. For example, the fine pattern 20 illustrated in FIG. 4A may be formed by, for example, the semi-additive process (SAP) and although not illustrated, for example, the seed layer may be formed by the methods such as an electroless process or a sputtering process, and the like. In the circuit patterning process, the pattern miniaturization of the SAP process is determined according to the surface of the insulating layer and therefore, when the surface roughness of the insulator is large, it is difficult to form the fine pattern on the surface of the insulator and it is possible to form the pattern even by the plating, for example, the tenting process after Cu is laminated, depending on the selectivity of the process, and the like.

Next, the process of laminating the first and second insulating layers and patterning of the pattern will be described with reference to FIGS. 2B to 2E or/and FIGS. 4B to 4E.

In the forming of the pattern by laminating the first and second insulating layers, at least one first insulating layer 30 made of the photosensitive resin material and at least one second insulating layer 50 made of the non-photosensitive resin material are laminated on the upper portion, the lower portion, or the upper and lower portions of the core layer 10 and the pattern is formed. The first insulating layer 30 is made of the photosensitive resin material such that the fine pattern can be formed by, for example, the photo exposure and development. On the other hand, the second insulating layer 50 is made of the non-photosensitive material and the laser punching is applied at the time of forming the via such that the wide via 45 having a larger size than the fine photo via 25 may be formed by the photo method.

In this case, the first insulating layer 30 may be formed by laminating the photosensitive resin film or by applying the photosensitive resin paste or the liquid phase. For example, the first insulating layer 30 may be formed by laminating the photosensitive resin film or applying the photosensitive resin paste or the liquid phase on the core layer 10 on which the circuit pattern illustrated in FIG. 2B is formed or the second insulating layer 50 on which the wide pattern layer 40 illustrated in FIG. 4D is formed. In one example, the photosensitive resin material used for the first insulating layer 30 may include at least any one selected from photosensitive polyhydroxystyrene (PHS), photosensitive polybenzoxazole (PBO), photosensitive polyimide (PI), photosensitive benzocyclobutene (BCB), photosensitive polysiloxane, photosensitive epoxy, and novolac resin.

Further, the second insulating layer 50 may be made of, for example, materials such as liquid crystal polymer (LCP), PPG (FR 1, 2, 3, 4), teflon, ajinomoto build up film (ABF), resin coated copper (RCC), and the like, but the exemplary embodiment of the present invention are not limited thereto.

Referring to FIGS. 2B to 2E or/and FIGS. 4B to 4E, in one example, in the process of laminating the first and second insulating layers, the hybrid lamination structure in which the first and second insulating layers 30 and 50 are mixed and laminated may be formed on the upper portion, the lower portion, or the upper and lower portions of the core layer 10. In this case, the first insulating layer 30 and the second insulating layer 50 may be alternately laminated, but may be laminated in a form in which at least one first insulating layer 30 is inserted between the plurality of second insulating layers 50 or as illustrated in FIG. 5, may also be laminated in a form in which at least second insulating layer 50 is inserted into the middle of the plurality of first insulating layers 30. For example, referring to FIGS. 2B to 2E, the hybrid lamination structure may be formed to have the hybrid structure in which the second insulating layer 50 is formed on the first insulating layer 30 or referring to FIGS. 4B to 4E, the hybrid lamination structure may be formed to have the hybrid structure in which the first insulating layer 30 is formed on the second insulating layer 50. Although not illustrated, in the hybrid lamination structure, the adhesive layer (not illustrated) may be interposed between the first insulating layer 30 and the second insulating layer 50 so as to firm the coupling between the heterogeneous insulators.

Further, although not illustrated, referring to FIG. 5, in the process of forming the pattern by laminating the first and second insulating layers, the first and second insulating layers 30 and 50 are punched by CNC or laser to form through holes 65, 65′, and 65″, thereby interconnecting the upper and lower portions of the hybrid lamination structure of the first and second insulating layers 30 and 50.

Further, according to one example, a process of laminating the first and second insulating layers and forming the pattern will be described. Referring to FIG. 2C or/and FIG. 4E, at least one fine via 25 having a smaller size is formed on the first insulating layer 30 and referring to FIG. 2E or/and 4C, at least one wide via 45 having a larger size may be formed on the second insulating layer 50. That is, referring to FIG. 2C or/and 4E, the fine via 25 may be formed by performing the exposure, development, and plating on the laminated first insulating layer 30 and referring to FIG. 2E or/and 4C, the wide via 45 may be formed by performing, for example, the laser drilling on the second insulating layer 50.

The first insulating layer 30 is made of the photosensitive material, such that the fine photo via 25 having a smaller size is formed by applying the photoresist and performing the exposure, development, and plating processes, thereby implementing the high density. In addition, the first insulating layer 30 may also be provided with the fine photo via 25 and if necessary, the wide laser via 45 having a larger size than the fine photo via 25 by performing, for example, the laser punching on the portions that may be formed at the low density, or as illustrated in FIG. 5, may also be provided with the through holes 65, 65′, and 65″ by using the CNC or laser. The fine photo via 25 using the photo method is generally formed to have a smaller size than a via that is physically machined using the laser drill. In addition, the size of the photo via 25 may be controlled according to the photo mask pattern size.

Meanwhile, the wide laser via 45 formed on the second insulating layer 50 is punched using Yag laser, CO₂ laser, and the like, and then, may be formed by plating or the filling of conductive materials. In this case, the second insulating layer 50 is made of the non-photosensitive material, such that it is difficult to form the fine photo via using the photo method.

The upper and lower patterns of the first insulating layer 30 may be connected with each other through the fine photo via 25 formed on the first insulating layer 30 and the upper and lower patterns of the second insulating layer 50 may be connected with each other through the wide laser via 45 formed on the second insulating layer.

Further, one example will be described with reference to FIG. 2C or/and FIG. 4E. In the laminating of the first and second insulating layers and the forming of the pattern, the fine pattern layer 20 including the signal transmission line may be formed on the upper portion of the first insulating layer 30. In this case, the fine pattern layer 20 including the signal transmission line may be connected with the fine photo via 25 that is formed on the first insulating layer 30. Meanwhile, the pattern formed on the lower portion of the first insulating layer 30 connected with the fine photo via 25 formed on the first insulating layer 30 may be a pattern that is formed on the upper portion of the core layer 10 forming the lower layer of the first insulating layer 30 illustrated in FIG. 2, the second insulating layer 50 illustrated in FIG. 4D, or another first insulating layer 30 (not illustrated). For example, the fine pattern layer 20 on the first insulating layer 30 may be formed by machining, for example, the copper clad layer (CCL) and by, for example, the MSAP, AMSAP process, and the like. Meanwhile, even when the fine pattern layer 20 and if necessary, the low-density pattern need to be formed on the upper portion of the first insulating layer 30, the wide pattern layer 40 may be formed.

To be continue, referring to FIG. 2E or/and FIG. 4C, in the laminating of the first and second insulating layers and the forming of the pattern, the wide pattern layer 40 including at least of the ground and the power distribution network (PDN) may be formed on the upper portion of the laminated second insulating layer 50. In this case, the wide pattern layer 40 formed on the upper portion of the second insulating layer 50 may be formed so as to be connected with the wide laser via 45. Further, the wide laser via 45 penetrating through the inside of the second insulating layer 50 is connected with the pattern formed on the lower portion of the second insulating layer 50. The wide pattern layer 40 on the second insulating layer 50 may be formed by etching, for example, the copper clad layer (CCL) and by, for example, the tenting process and in some cases, may also be formed by using the MSAP or AMSAP process.

Next, another example will be described with reference to FIG. 2F or/and FIG. 4F.

In this case, as illustrated in FIG. 2F or/and FIG. 4F, after the laminating of the first and second insulating layers and the forming of the pattern, the manufacturing method of the hybrid lamination substrate may further include forming the solder resist (SR) layer 70 at the outside of the lamination structure. That is, as illustrated in FIG. 2F, the solder resist layer 70 may be formed on the second insulating layer 50 on which the wide laser via 45 is formed or as illustrated in FIG. 4F, the solder resist layer 70 may be formed on the first insulating layer 30 on which the fine photo via 25 is formed. In this case, the solder resist layer 70 serves to protect the circuit pattern on the first insulating layer 30. For example, the solder resist layer 70 may be made of the photosensitive resin.

Further, when the hybrid lamination substrate is the lamination substrate in which electronic devices are embedded, in the forming of the circuit pattern on the core layer 10, the cavity 11 may be formed on the core layer 10 and electronic devices 15 may be embedded in the cavity.

Alternatively, although not illustrated, in the laminating of the first and second insulating layers and the forming of the pattern, the first and second insulating layers 30 and 50 are mixed and laminated and the hybrid lamination structure of the laminated first and second insulating layers 30 and 50 may be the hybrid lamination structure of the first and second insulating layers 30 and 50 in which the cavity (not illustrated) is formed by, for example, the CNC punching or other methods and the electronic devices (not illustrated) are embedded in the cavity (not illustrated).

As set forth above, according to the exemplary embodiments of the present invention, it is possible to reduce the laminated thickness by implementing the optimization of the design and reduce the costs of the lamination substrate by effectively using the expensive lamination material and process, when using the structure of the hybrid lamination substrate and the manufacturing method thereof.

Further, it is possible to reduce the lamination layer by appropriately adjusting the fine via layer, for example, the photo via layer, and the wide via layer, for example, the laser via layer at the time of manufacturing the lamination substrate.

Further, it is possible to reduce the process costs by mixing the photosensitive material and the general non-photosensitive substrate material such as prepreg (PPG). In addition, it is possible to apply the optimal pattern width to each layer by using the photosensitive material and the general non-photosensitive substrate material.

Further, it is possible to reduce the lamination layer and optimize the substrate manufacturing process and the substrate lamination structure, by appropriately combining the layers, such as the ground GND, the power distribution network (PDN), and the like, to which the wide pattern is applied and the layer requiring the fine pattern such as the signal transmission line, and the like, according to each main role of each layer at the time of configuring the substrate.

The accompanying drawings and the above-mentioned exemplary embodiments have been illustratively provided in order to assist in understanding of those skilled in the art to which the present invention pertains rather than limiting a scope of the present invention. In addition, exemplary embodiments according to a combination of the above-mentioned configurations may be obviously implemented by those skilled in the art. Therefore, various exemplary embodiments of the present invention may be implemented in modified forms without departing from an essential feature of the present invention. In addition, a scope of the present invention should be interpreted according to claims and includes various modifications, alterations, and equivalences made by those skilled in the art.

1. A hybrid lamination substrate, comprising:
a core layer;
at least one first insulating layer that is made of a photosensitive resin material and is formed on an upper portion, a lower portion, or upper and lower portions of the core layer; and
at least one second insulating layer that is made of a non-photosensitive resin material and is formed on the upper portion, the lower portion, or the upper and lower portions of the core layer.

2. The hybrid lamination substrate according to claim 1, wherein a hybrid lamination structure in which the first and second insulating layers are mixed and laminated on the upper portion, the lower portion, or the upper and lower portions of the core layer is formed.

3. The hybrid lamination substrate according to claim 2, wherein a through hole is formed within the hybrid lamination structure so as to interconnect the upper and lower portions of the insulating layer.

4. The hybrid lamination substrate according to claim 1, wherein the first insulating layer includes at least one fine via having a smaller size that connects patterns formed on the upper and lower portions thereof, and
the second insulating layer includes at least one wide via having a larger size that connects patterns formed on the upper and lower portions thereof.

5. The hybrid lamination substrate according to claim 4, wherein the fine via is a photo via and a fine pattern layer formed on the upper portion of the first insulating layer and including a signal transmission line is connected with the photo via, and
the wide via is a laser via and a wide pattern layer formed on the upper portion of the second insulating layer and including at least any one of a ground and a power distribution network (PDN) is connected with the laser via.

6. The hybrid lamination substrate according to claim 4, wherein the fine via is a photo via and the wide via is a laser via, and
the plurality of photo vias formed on the first insulating layer have at least two different sizes.

7. The hybrid lamination substrate according to claim 1, wherein the photosensitive resin material of the first insulating layer includes at least any one selected from photosensitive polyhydroxystyrene (PHS), photosensitive polybenzoxazole (PBO), photosensitive polyimide (PI), photosensitive benzocyclobutene (BCB), photosensitive polysiloxane, photosensitive epoxy, and novolac resin.

8. The hybrid lamination substrate according to claim 1, wherein the second insulating layer is made of any one of prepreg (PPG), ajinomoto build-up film (ABF), resin coated copper (RCC), liquid crystal polymer (LCP), and teflon.

9. The hybrid lamination substrate according to claim 1, further comprising:
a solder resist (SR) layer that is formed at an outer layer of the lamination substrate.

10. The hybrid lamination substrate according to claim 1, wherein the core layer includes a cavity, and
the cavity has electronic devices embedded therein, and
the core layer in which the electronic devices are embedded is laminated with the first and second insulating layers.

11. The hybrid lamination substrate according to claim 1, wherein the hybrid lamination structure in which the first and second insulating layers are mixed and laminated is provided with the cavity, and
the cavity has electronic devices embedded therein.

12. A package substrate including an IC, comprising:
the hybrid lamination substrate according to claim 1; and
an IC chip mounted on the hybrid lamination substrate or mounted therein.

13. The package substrate according to claim 12, wherein the IC chip is mounted at an outside of the hybrid lamination structure in which first and second insulating layers are mixed and laminated on an upper portion, a lower portion, or upper and lower portions of the core layer, and
an insulating layer close to the IC chip is the first insulating layer and an inside of the insulating layer far away from the IC chip is provided with the second insulating layer.

14. The package substrate according to claim 12, wherein the IC chip is embedded in a cavity formed at an inside of the hybrid lamination structure in which first and second insulating layers are mixed and laminated on an upper portion, a lower portion, or upper and lower portions of the core layer.

15. A manufacturing method of a hybrid lamination substrate, comprising:
preparing a core layer and forming a circuit pattern on the core layer; and
laminating at least one first insulating layer made of a photosensitive resin material and at least one second insulating layer made of a non-photosensitive material on an upper portion, a lower portion, or upper and lower portions of the core layer and forming a pattern.

16. The manufacturing method according to claim 15, wherein in the laminating of the first and second insulating layers, a hybrid lamination structure in which the first and second insulating layers are mixed and laminated on the upper portion, the lower portion, or the upper and lower portions of the core layer is formed.

17. The manufacturing method according to claim 15, wherein in the laminating of the first and second insulating layers and the forming of the pattern,
at least one fine photo via having a smaller size that connects upper and lower patterns of the first insulating layer is formed by performing exposure, development, and plating on the laminated first insulating layer, and
at least one wide laser via having a larger size that connects patterns formed on upper and lower portions of the second insulating layer is formed by performing laser drilling on the laminated second insulating layer.

18. The manufacturing method according to claim 17, wherein in the laminating of the first and second insulating layers and the forming of the pattern,
a fine pattern layer including a signal transmission line is formed on the upper portion of the first insulating layer so as to be connected with the fine photo via, and
a wide pattern layer including any one of a ground and a power distribution network (PDN) is formed on the upper portion of the second insulating layer so as to be connected with the wide laser via.

19. The manufacturing method according to claim 15, further comprising:
after the laminating of the first and second insulating layers and the forming of the pattern, forming a solder resist (SR) layer at an outside of the hybrid lamination substrate.
